(19) United States
(12) Patent Application Publication
(10) Pub. No.: US 2025/0124963 A1
(43) Pub. Date: Apr. 17, 2025

(54) APPARATUSES AND METHODS FOR PER-ROW COUNT BASED REFRESH TARGET IDENTIFICATION WITH SORTING

(71) Applicant: Micron Technology, Inc., Boise, ID (US)

(72) Inventor: Yang Lu, Boise, ID (US)

(73) Assignee: Micron Technology, Inc., Boise, ID (US)

(21) Appl. No.: 18/744,988

(22) Filed: Jun. 17, 2024

Related U.S. Application Data
(60) Provisional application No. 63/589,724, filed on Oct. 12, 2023.

(51) Int. Cl. G11C 11/406

(52) U.S. Cl. CPC G11C 11/406

(57) ABSTRACT

Apparatuses and methods for per-row count based refresh target identification with sorting. A memory includes a number of word lines each associated with a row address and a count value. A targeted refresh queue stores the highest count values and their row addresses as an ordered list. For example the list may be sorted from highest count value to lowest count value. During a targeted refresh operation, the row address at a top of the queue is used for refresh operations and removed from the queue. When a row and count value are added to the queue, the queue is re-sorted.

### CROSS REFERENCE TO RELATED APPLICATION(S)

This application claims the benefit under 35 U.S.C. § 119 of the earlier filing date of U.S. Provisional Application Ser. No. 63/589,724 filed Oct. 12, 2023, the entire contents of which are hereby incorporated by reference in its entirety for any purpose.

### BACKGROUND

Information may be stored on memory cells of a memory device. The memory cells may be organized at the intersection of word lines (rows) and bit lines (columns). Information in the memory cells may decay over time. For example, the information may be stored as a charge on a capacitor which may decay over time. The memory device may perform refresh operations to restore the information and prevent information from being lost.

Certain patterns of access may cause an increased rate of information decay in nearby memory cells (e.g., the memory cells along nearby word lines). Memories may use various schemes to identify which memory cells are affected by such patterns such that targeted refresh operations can be performed before those memory cells lose their information. There may be a need to balance the targeted refresh operations with the time and power they use.

### BRIEF DESCRIPTION OF THE DRAWINGS

FIG. 1 is a block diagram of a semiconductor device according to an embodiment of the present disclosure.

FIG. 2 is a block diagram of a refresh control circuit according to an embodiment of the present disclosure.

FIG. 3 is a block diagram of an aggressor detector circuit according to some embodiments of the present disclosure.

FIG. 4 is a chart of example operations in a targeted refresh queue according to some embodiments of the present disclosure.

FIG. 5 is a flow chart of a method of managing a targeted refresh queue according to some embodiments of the present disclosure.

FIG. 6 is a flow chart of a method of performing targeted refresh operations according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Information in a memory array may be accessed by one or more access operations, such as read or write operations. During an example access operation a word line may be activated based on a row address and then selected memory cells along that active word line may have their information read or written to based on which bit lines are accessed, which may be based on a column address. The memory array may be refreshed on a row by row basis (e.g., as part of an auto-refresh and/or self-refresh mode) where the memory cells along each row are refreshed periodically. The speed at which the rows are refreshed (e.g., the maximum time any given row will go between refreshes) may be determined based on an expected rate of information decay.

Various patterns of access to a row (an aggressor row) may cause an increased rate of information decay in nearby memory cells (e.g., along victim rows). For example, a ‘row hammer’ may involve repeated accesses to the aggressor row which may increase a rate of decay in adjacent rows (and/or in rows which are further away). Accordingly, it may be important to track a number of accesses to each row to determine if they are aggressors, such that the victim rows can be identified and refreshed as part of a targeted refresh operation. For example, each word line may have an associated count value which is used to determine how many times that word line has been accessed. Based on those access counts, rows may be identified for targeted refresh operations. There may be a need to manage how the memory identifies rows to balance detecting rows so they can be refreshed before information is lost against the time and power that those targeted refresh operations use. There may be a need to ensure that potential aggressors are identified while filtering out un-needed targeted refresh operations.

The present disclosure is drawn to apparatuses, systems, and methods for per-row count based refresh target identification with sorting. A memory device includes a number of word lines, each of which stores a count value. When the word line is accessed, the count value is updated. A refresh control circuit includes a targeted refresh queue which stores the N highest count values along with the row addresses associated with the word lines those count values are stored on. For example, when a count value is updated it is compared to the stored count values, and if it is greater than at least one, it is added to the queue along with its row address. The targeted refresh queue is an ordered list, which is sorted based on the stored count values. For example, the targeted refresh queue includes a number of slots, each of which stores a count value, an address, and an order tag. When a count value is changed, (e.g., because a word line is accessed or because a new count/row address are added) the targeted refresh queue is sorted and the order tags are updated to reflect the sorting order. For example, the count values may be compared and the order tags may be based on an order of the count values from greatest to least. When a targeted refresh operation is called for a row address at the top of the sort order of the queue (e.g., associated with the highest value order tag) is removed from the queue and provided as an aggressor address and one or more word lines based on the aggressor address are refreshed.

In some embodiments, a mitigation threshold may be used to help reduce unnecessary targeted refresh operations. For example the mitigation threshold may be used to determine if the row address should be added to the queue or may be used to determine if the row address should be provided from the queue as an aggressor address. In an example embodiment, when a count value is updated it may be compared to the mitigation threshold, if it has not crossed the threshold, it is not compared to the count values in the targeted refresh queue and the sort of the queue is not updated. If there are not addresses in the queue when the targeted refresh operation is called for, the targeted refresh operation may be skipped.

In another example embodiment, when a count value is updated it is compared to the count values in the targeted refresh queue, and the sort of the targeted refresh queue is updated. Responsive to a targeted refresh operation being called for, the count value at the top of the sort order is compared to the threshold, and if the address has crossed the threshold, the address is provided as the aggressor and removed from the queue. If the count has not crossed the threshold then the address remains in the queue and the targeted refresh operation may be skipped.

The present disclosure is generally described with respect to example embodiments where, when a word line is accessed the associated count value is increased. Accordingly, comparisons may generally refer to determining if the updated count value is ‘greater than’ or ‘greater than or equal to’ other values (e.g., stored count values, thresholds etc.). However, a person of skill in the art would recognize that the direction of counting may different in other example embodiments. For example, the count value may be decreased when the word line is accessed. In such embodiments, the terminology described above should be understood to mean determining when the updated count is less than or less than or equal to those other values.

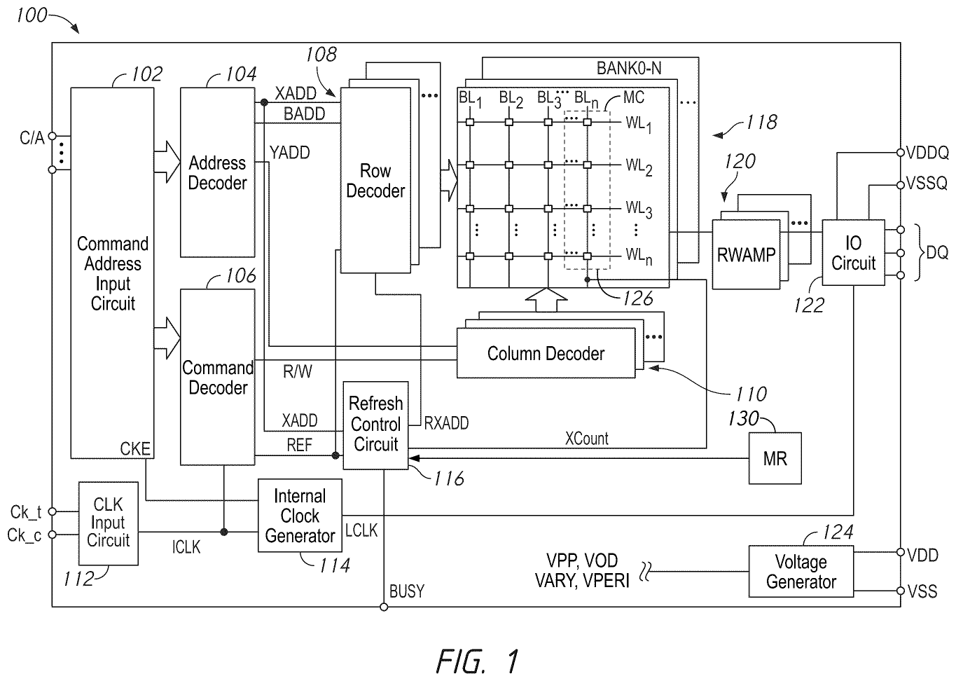

FIG. 1 is a block diagram of a semiconductor device according to at least one embodiment of the disclosure. The semiconductor device 100 may be a semiconductor memory device, such as a DRAM device integrated on a single semiconductor chip.

The semiconductor device 100 includes a memory array 118. The memory array 118 is shown as including a plurality of memory banks. In the embodiment of FIG. 1, the memory array 118 is shown as including eight memory banks BANK0-BANK7. More or fewer banks may be included in the memory array 118 of other embodiments. Each memory bank includes a plurality of word lines WL (rows), a plurality of bit lines BL (columns), and a plurality of memory cells MC arranged at intersections of the plurality of word lines WL and the plurality of bit lines BL.

The selection of the word line WL is performed by a row decoder 108 and the selection of the bit lines BL is performed by a column decoder 110. In the embodiment of FIG. 1, the row decoder 108 includes a respective row decoder for each memory bank and the column decoder 110 includes a respective column decoder for each memory bank. The bit lines BL are coupled to a respective sense amplifier (SAMP). Read data from the bit line BL is amplified by the sense amplifier SAMP, and transferred to read/write amplifiers 120 over complementary local data lines (LIOT/B), transfer gate (TG), and complementary main data lines (MIOT/B). Conversely, write data outputted from the read/write amplifiers 120 is transferred to the sense amplifier SAMP over the complementary main data lines MIOT/B, the transfer gate TG, and the complementary local data lines LIOT/B, and written in the memory cell MC coupled to the bit line BL.

Some of the memory cells may be set aside as counter memory cells 126. The counter memory cells may store count values XCount, each of which is associated with one of the word lines. Each count value XCount may be stored in counter memory cells 126 along the word line that the count value is associated with. The count value XCount may be stored as a binary number, with each bit stored in a memory cell along the word line. For the sake of clarity, a single bit line of counter memory cells 126 is shown in FIG. 1. The number of counter memory cells along each word line may be based on a number of bits of the count value XCount. In some embodiments, extra counter memory cells (e.g., more than the length of the number XCount) may be used, for example to store error correction information for the count value XCount.

The counter memory cells 126 may be referred to as such due to their use (storing the count values) and in some embodiments may be structurally similar to, or identical to, the other memory cells of the array. In some embodiments, the counter memory cells 126 may be grouped together (e.g., at the end of the word line). Other distributions of the counter memory cells 126 along the word line may be used in other example embodiments. In some embodiments, the counter memory cells 126 may not be directly accessible by external devices such as controllers (e.g., to prevent the count values from being overwritten). In other words, the bit lines associated with the counter memory cells 126 may not be accessed by a normal column address.

The semiconductor device 100 may employ a plurality of external terminals that include command and address (C/A) terminals coupled to a command and address bus to receive commands and addresses, and a CS signal, clock terminals to receive clocks CK and /CK, data terminals DQ to provide data, and power supply terminals to receive power supply potentials VDD, VSS, VDDQ, and VSSQ.

The clock terminals are supplied with external clocks CK and /CK that are provided to an input circuit 112. The external clocks may be complementary. The input circuit 112 generates an internal clock ICLK based on the CK and /CK clocks. The ICLK clock is provided to the command decoder 110 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data.

The C/A terminals may be supplied with memory addresses. The memory addresses supplied to the C/A terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The C/A terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations. For example, the command decoder 106 may provide a row command signal to select a word line and a column command signal to select a bit line.

The device 100 may receive an access command which is a row activation command ACT. When the row activation command ACT is received, a bank address BADD and a row address XADD are timely supplied with the row activation command ACT.

The device 100 may receive an access command which is a read command. When a read command is received, a bank address BADD and a column address YADD are timely supplied with the read command, read data is read from memory cells in the memory array 118 corresponding to the row address XADD and column address YADD. The read command is received by the command decoder 106, which provides internal commands so that read data from the memory array 118 is provided to the read/write amplifiers 120. The read data is output to outside from the data terminals DQ via the input/output circuit 122. The access count XCount stored counter memory cells 126 of the row associated with the row address XADD are read to the refresh address control circuit 116, and an updated value of the access count XCount′ is written back to the counter memory cells 126 of the row XADD.

The device 100 may receive an access command which is a write command. When the write command is received, a bank address BADD and a column address YADD are timely supplied with the write command, write data supplied to the data terminals DQ is written to a memory cells in the memory array 118 corresponding to the row address and column address. The write command is received by the command decoder 106, which provides internal commands so that the write data is received by data receivers in the input/output circuit 122. Write clocks may also be provided to the external clock terminals for timing the receipt of the write data by the data receivers of the input/output circuit 122. The write data is supplied via the input/output circuit 122 to the read/write amplifiers 120, and by the read/write amplifiers 120 to the memory array 118 to be written into the memory cell MC. Similar to the read operation described above, the access count Xcount stored in counter memory cells 126 of the row associated with the row address XADD are read to the refresh address control circuit 116, and an updated value of the access count Xcount′ is written back to the counter memory cells 126 of the row XADD.

The device 100 may also receive commands causing it to carry out refresh operations. For example, a controller of the memory may put the device 100 into an auto-refresh mode and provide refresh signal REF. The device 100 may also enter a self-refresh mode where the refresh signal is generated internally. Since other than the source of the refresh signal, the two operations may generally be similar, the present disclosure will generally describe auto-refresh operations (for example the refresh signal may be referred to as an ‘auto-refresh signal’). However, it should be understood that the present disclosure may apply to self-refresh (or other refresh modes) as well.

The refresh signal REF may be a pulse signal which is activated when the command decoder 106 receives a signal which indicates an auto-refresh command. In some embodiments, the auto-refresh command may be externally issued to the memory device 100. In some embodiments, the auto-refresh command may be periodically generated by a component of the device (e.g., as part of a self-refresh mode). In some embodiments, when an external signal indicates a self-refresh entry command, the refresh signal REF may also be activated. The refresh signal REF may be activated once immediately after command input, and thereafter may be cyclically activated at desired internal timing. Thus, refresh operations may continue automatically. A self-refresh exit command may cause the automatic activation of the refresh signal REF to stop and return to an IDLE state.

The refresh signal REF is supplied to the refresh address control circuit 116. The refresh address control circuit 116 supplies a refresh row address RXADD to the row decoder 108, which refreshes a wordline WL identified by the refresh row address RXADD. The refresh address control circuit 116 controls a type of refresh operation with timing based on the refresh signal REF, and generates and provides the refresh address RXADD. The refresh address control circuit 116 may be controlled to change details of the refreshing address RXADD (e.g., how the refresh address is calculated, the timing of the refresh addresses), or may operate based on internal logic.

The refresh control circuit 116 may perform one or more refresh operations responsive to the refresh signal REF. The one or more refresh operations may include normal (or sequential) refresh operations, targeted refresh operations or a combination thereof. As part of performing the one or more refresh operations, the refresh control circuit 116 provides a refresh address RXADD (along with one or more internal refresh signals, not shown in FIG. 1). As part of a normal refresh operation, the refresh control circuit 116 generates and provides a normal refresh address as RXADD. As part of a targeted refresh operation, the refresh control circuit generates and provides a targeted refresh address as RXADD. In some embodiments the normal refresh addresses may be associated with more word lines than the targeted refresh addresses and all of the word lines associated with the normal refresh address may be refreshed at once as part of a normal refresh operation. For example, the normal refresh address may be truncated compared to a row address XADD, and each word line that's address shares the truncated portion in common may be refreshed at once.

The normal refresh addresses may be generated based on a sequence of addresses. For example, each sequential refresh may be based on a previous normal refresh address (e.g., RXADD (i)=RXADD (i−1)+1). The refresh address control circuit 116 may cycle through the sequence of sequential addresses at a rate determined by REF. In some embodiments, the sequence of sequential addresses may include all the addresses in the memory bank 118. In some embodiments, the refresh signal REF may be issued with a frequency such that most or all of the addresses in the memory bank 118 are refreshed within a certain period (e.g., such that there is a maximum specified time between two consecutive sequential refreshes of a given word line), which may be based on an expected rate at which information in the memory cells MC decays.

The refresh address control circuit 116 also performs targeted refresh operations. As part of a targeted refresh operation the refresh address control circuit generates one or more refresh addresses based on an identified aggressor address. The aggressor addresses are row addresses identified as aggressors based on the count value XCount associated with that address. The refresh control circuit 116 includes a targeted refresh queue which stores aggressor addresses. The targeted refresh queue is a sorted list which stores addresses and their count values, and sorts the list based on the count values. For example, the targeted refresh queue may include a number of slots each of which stores an address, a count value, and an order tag. The order tag may be a numerical value which indicates a position of that slot's contents in the ordered list. In some embodiments, a higher value of the order tag may indicate a position closer to the top of the queue, although other ways of associating the value of the order tags with the queue order may be used in other embodiments.

When a row is accessed, the count value XCount is read out and updated (e.g., by being incremented). The row address is compared to the stored row addresses. If there is a match (e.g., the row address is already in the queue) the stored count value associated with that stored address is updated to match the updated count value and the queue is resorted to account for the updated count value. If there is not a match (e.g., the address was not already stored) the updated count value may be used to determine if the updated count value and address should be added to the queue. For example, if the updated count value is greater than one or more count values in the queue, then the updated count value and its associated row address are added to the queue, and the queue is sorted again. If the queue is too full, the count and address which previously had lowest position in the queue's order are removed. In this manner the targeted refresh queue may store an ordered list of the addresses with the N highest count values.

When a targeted refresh operation is called for, either by the internal logic of the refresh control circuit 116 or due to an external command such as a refresh management (RFM) command, the refresh control circuit 116 generates one or more refresh addresses based on the address at the top of the target address queue (e.g., the address in the slot with the highest value order tag). Responsive to the address being used for one or more targeted address operations, the address and count value may be removed from the queue. When the address and count value are removed from the queue, the count value in the counter memory cells 126 is reset (e.g., to an initial value such as 0).

In some embodiments, a threshold may be used to help reduce unnecessary refreshes. For example, when the count value XCount is updated, it may be compared to the threshold before the count and address are compared to the stored counts and addresses in the targeted refresh queue. If the count has crossed the threshold (e.g., is greater than or equal to the threshold value), then it is compared. If the count has not crossed the threshold (e.g., is less than the threshold), the updated count value is written back to the counter memory cells 126, but not compared to the stored counts and addresses in the queue. In this way, all the stored count values in the queue may have crossed the threshold. In another example implementation, the mitigation threshold may be applied to the count value with the highest position when a targeted refresh is called for, in this manner the count values in the queue may or may not have crossed the threshold, but only count values which have crossed the threshold will have their associated addresses used to generate targeted refresh addresses.

The threshold may be a setting of the memory device 100 in some embodiments. For example, a mode register 130 may store the threshold value. The mode register 130 may store a collection of registers, each of which store settings and/or information about the memory device. Some registers may be modified by a controller (e.g., to change settings) via mode register write operation. Some registers may be set by a non-volatile storage element on the memory, such as a fuse array. The controller may perform mode register read operations to determine the state of selected registers. A mitigation threshold register may set a value of the mitigation threshold. If the threshold is increased, fewer targeted refresh operations will occur and if it is decreased, more will occur. If the threshold is set to 0, then a targeted refresh will always be performed when a targeted refresh is called for.

The refresh control circuit 116 may use different methods to calculate a targeted refresh address based on the aggressor address based on the access count. For example the victim addresses may include word lines adjacent to the aggressor word line (e.g., XADD+1 and XADD−1) and/or may include word lines further away (e.g., XADD+/−2, XADD+/−3, etc.). In some embodiments, more than one victim address may correspond to a given aggressor address. In this case the refresh address control circuit may queue up multiple targeted refresh addresses, and provide them sequentially when it determines that a targeted refresh address should be provided. The refresh address control circuit 116 may provide the targeted refresh address right away, or may queue up the targeted refresh address to be provided at a later time (e.g., in the next time slot available for a targeted refresh).

In some embodiments, the refresh control circuit may include two targeted refresh queues, each of which may be associated with different targeted refresh address calculations. For example, the first queue may store addresses (and count values) used for XADD+/−1 refresh addresses, while the second queue may store addresses (and count values) used for XADD+/−2 refresh addresses. In some embodiments, the first queue may be a sorted queue, while the second queue may be a non-sorted queue (e.g., FIFO). The refresh control circuit may use internal logic to determine when to retrieve addresses from the first queue (and generate RXADD=XADD+/−1) and when to retrieve addresses from the second queue (and generate RXADD=XADD+/−2).

The power supply terminals are supplied with power supply potentials VDD and VSS. The power supply potentials VDD and VSS are supplied to an internal voltage generator circuit 124. The internal voltage generator circuit 124 generates various internal potentials VPP, VARY, VPERI, and the like based on the power supply potentials VDD and VSS supplied to the power supply terminals. The internal potential VPP is mainly used in the row decoder 108, the internal potentials VARY are mainly used in the sense amplifiers SAMP included in the memory array 118, and the internal potential VPERI is used in many peripheral circuit blocks.

The power supply terminals are also supplied with power supply potentials VDDQ and VSSQ. The power supply potentials VDDQ and VSSQ are supplied to the input/output circuit 122. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

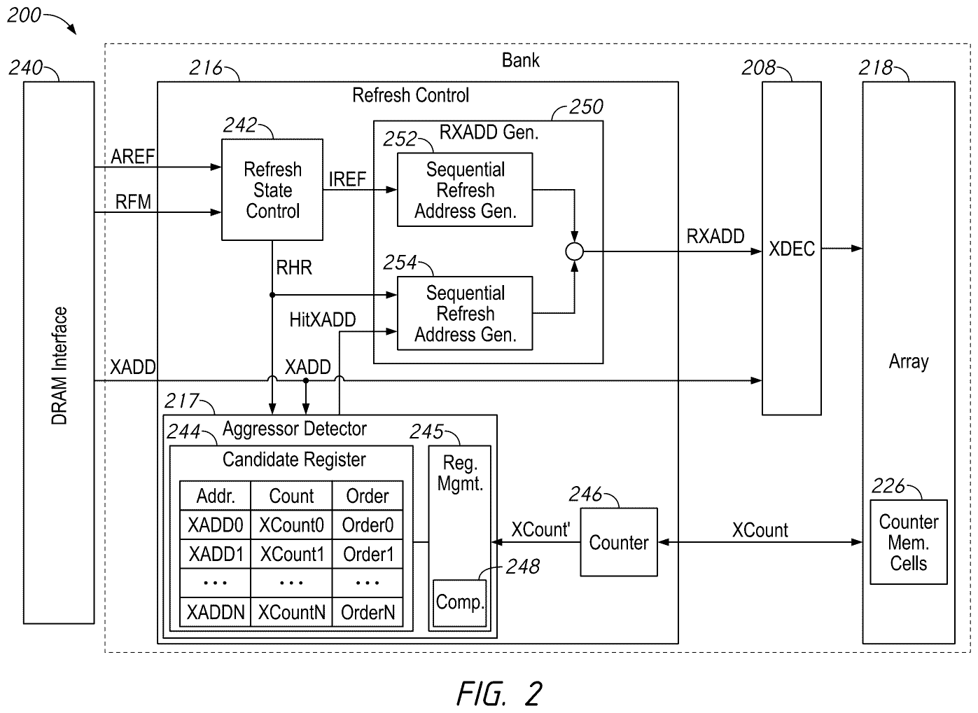

FIG. 2 is a block diagram of a refresh control circuit according to an embodiment of the present disclosure. FIG. 2 may show an example layout of portions of a memory 200 which may implement a portion of a memory device, such as the memory device 100 of FIG. 1. For example, the memory array 218 may implement the memory array 118 of FIG. 1, the row decoder 208 may implement the row decoder 108 of FIG. 1, the refresh control circuit 216 may implement the refresh control circuit 116 of FIG. 1 and so forth.

Certain internal components and signals of the refresh address control circuit 216 are shown to illustrate the operation of the refresh address control circuit 216. For example, the refresh control circuit 216 may include an RHR state control circuit 242 which determines if sequential or targeted refreshes are performed, an aggressor detector circuit 217 which identifies addresses as aggressors HitXADD, and a refresh address generator 250 which generates the refresh address RXADD. Also shown is a counter circuit 246 which manages the values of XCount stored in the counter memory cells 226 of the memory array 218.

The dotted line around the refresh address control circuit 216, the row decoder 208, and the memory array 218 is shown to represent that in certain embodiments, each of the components within the dotted line may correspond to a particular bank of memory, and that these components may be repeated for each of the banks of memory. In some embodiments, the components shown within the dotted line may be associated with each of the memory banks. Thus, there may be multiple refresh address control circuits 216 and row decoders 208. For the sake of brevity, components for only a single bank will be described.

FIG. 2 shows components, such as the counter 246, aggressor detector 217, refresh state control circuit 242 and refresh address generator 250, grouped together as part of the refresh control circuit 216. However, one or more of these components may be spatially distributed throughout the memory. For example, the aggressor detector circuit 217 and the counter circuit 248 may be spatially located in a logic region closer to the bank while the other components of the refresh control circuit may be in a bank logic region. Other distributions may be used in other example embodiments.

A DRAM interface 240 may provide one or more signals to a refresh control circuit 216 and row decoder 208 which in turn (along with a column decoder, not shown) may perform access operation on a memory array 218. When a row of the memory array 218 is accessed, the values of the counter memory cells 226 along that row are read to the counter circuit 246. For example, the counter memory cells 226 may store the bits of a binary number that represents the count value. For example, if the number is a 16-bit number, then 16 or more counter memory cells may store the bits of the number.

The counter 246 may determine a value of the access count for that row based on the values read from the counter memory cells 226. The counter 246 may be a count control circuit, which may manage a value of the count stored in the counter memory cells 226 (e.g., by reading the raw data in the counter memory cells 226 as a numerical value, writing new numerical values to the counter memory cells 226 etc.). The counter circuit 246 may change the count value (e.g., by incrementing the count value) write the changed count value back to the counter memory cells and provide the changed count value to the aggressor detector circuit 217. The aggressor detector circuit 217 includes a targeted refresh queue 244 and a register management circuit 245. The targeted refresh queue 244 stores row addresses and their associated count values along with an order tag which indicates a sort order of the list.

During an access operation, the register management circuit 245 compares the accessed row address XADD to the stored addresses. If the address XADD matches, then its count value in the queue 244 is updated to XCount′ and the register management circuit 245 resorts the queue and updates the order tags. If there is not a match, the updated count value XCount′ is compared to the stored count values to determine if the updated count value XCount′ and row address XADD should be added. For example, the register management circuit 245 may determine if there is an open slot in the queue 244 or if the updated count value XCount′ is greater than at least one of the stored count values and stores the updated count value XCount′ and row address XADD. If the queue was full, the slot with the order tag at the bottom of the order is overwritten. When the updated count and row address are added, the list is re-sorted by the register management circuit 245 and the order tags are updated. If there is a not an open slot and the updated count value XCount′ is less than the stored count values, then the updated count value XCount′ and row address are not added to the queue 244.

During refresh operations (e.g., responsive to REF and/or RFM) the refresh state controller 242 determines a type of refresh operation and provides internal refresh signals IREF and/or RHR. The signal RHR indicates that a targeted refresh operation should be performed. Responsive to RHR, the aggressor detector circuit 217 provides the stored row address at the top of the targeted refresh queue 244 (e.g., the address in the slot with the highest order tag) as an aggressor HitXADD to the refresh address generator 250, which generates one or more refresh addresses RXADD based on the aggressor HitXADD. The row decoder 208 then performs a refresh operation on the word line indicated by RXADD. An additional operation is performed to have the counter 246 read out of the count value XCount associated with the aggressor HitXADD from the counter memory cells 226 and reset that count (e.g., to an initial value such as 0). The register management circuit 245 removes the row address, count value, and order tag of the address HitXADD from the queue 244.

The DRAM interface 240 may represent one or more components which provides signals to components of the bank. For example, the DRAM interface 240 may represent components such as the command address input circuit 102, the address decoder 104, and/or the command decoder 106 of FIG. 1. The DRAM interface 240 may provide a row address XADD, the auto-refresh signal REF and various other signals not shown in FIG. 2, such as row activation signals ACT and pre-charge signals Pre. The auto-refresh signal REF may be a periodic signal which may indicate when an auto-refresh operation is to occur. The row address XADD may be a signal which specifies one or more particular wordlines of the memory array 218, and may be a signal including multiple bits (which may be transmitted in series or in parallel). The DRAM interface 240 may also provide a refresh management command RFM, which is received from a controller of the memory.

The aggressor detection circuit 217 includes a targeted refresh queue 244 which stores a set of row addresses and their associated count values. The candidate register 244 includes a number of slots, each of which stores an address and count value. The slots are ordered. For example, each slot may also store an order tag, which may be a numerical value which indicates the position of that slot's contents in the ordered list of the queue. Other methods may be used in other example embodiments to associate the slots with a position in the queue. For example, in some embodiments, the order tags may be stored external to the slots (e.g., in the register management circuit 245), or the position of the slots may be used as the order tags (e.g., the contents of the first slot is first in the queue, and the contents are moved between slots when re-sorted).

When a row is accessed, the count value is read out from the counter memory cells 226 and updated by the counter circuit 246. In some embodiments, the count value may be updated by a fixed amount (e.g., incremented). In some embodiments, the count value may be updated based on a length of time that the word line remains active. The updated count value XCount′ is provided to the register management circuit 245 and written back to the counter memory cells 226 of the word line.

The register management circuit 245 receives the row address XADD from the row address bus and the updated count value XCount′ from the counter circuit 246 and determines if the address XADD and updated count value XCount′ should be added to the queue 244. The register management circuit 245 includes one or more comparator circuits 248 which may be used to compare the row address XADD to the stored row addresses XADD or to compare the stored count values to each other, the updated count value XCount′, one or more threshold values or combinations thereof.

In some embodiments, before performing other comparisons, the register management circuit 245 may compare the updated count value XCount′ to a threshold. If the count value has not crossed the threshold, then the comparison of the updated count value XCount′ and row address XADD to the contents of the queue 244 may be skipped. This may help to ensure that only count values which have crossed the threshold are stored (along with their respective row addresses).

The register management circuit 245 compares the row address to the stored row addresses. If there is a match, the stored count value in the same slot as the matching row address is overwritten with the updated count value XCount′ by the register management circuit 245. If there is not a match, then the register management circuit 245 checks to see if there is an empty or open slot. If so, then the address XADD and updated count value XCount′ are added. In some embodiments, if there is an empty slot, if the count value XCount′ is below the threshold (e.g., in embodiments where no comparison with the threshold was done before comparing to the queue contents) then either the value of the threshold or the updated count value XCount′, whichever is greater, is added. If there is not an empty slot, then the register management circuit 245 determines if the updated count value XCount′ is greater than at least one stored count value. If it is not, then the address and updated count value are not added to the queue. If it is, then the address and count value are used to overwrite the address and count value in the slot which was on a bottom of the sort order (e.g., with a lowest value of order tag). In some embodiments, if the count value XCount′ matches (e.g., is equal to) the lowest stored count value, the row address may be stored in that slot. In some embodiments, the row address may not be added if the count value XCount′ matches the lowest stored count value.

When a stored count value is updated or when a new address and count value is added to the queue 244, the register management circuit 245 performs a sort operation and adjusts the order of the queue accordingly (e.g., by updating the order tags as needed). The register management circuit 245 may sort the queue 244 based on the stored count values. For example, the slots may be sorted in order from highest count value (e.g., which may be assigned the highest order tag) to lowest count value (e.g., which may be assigned the lowest order tag). The comparator circuit 248 may be used to perform various comparisons between the stored count values to perform the sort operation. For example, the register management circuit 245 may use a sorting algorithm such as a bubble sort to perform the sort operation.

In an example implementation of a sort operation, the comparator 248 may perform a first comparison between XCount′ and the count value in the slot with the lowest order tag. If XCount′ is larger than the stored value, replace the stored row address with XADD and count value with XCount′. If XCount′ is not bigger, then the sort operation is done. If the sort operation continues, the comparator 248 may then perform a second comparison operation between the count value with the lowest order tag (e.g., XCount′) and the next lowest order tag. If the count value with the lower tag is bigger, then swap the values of the order tags. If the count value with the lower tag is not bigger, then the sort operation is done. If the sort operation continues, then compare XCount′ to the count value with the next highest order tag and so forth until the operation terminates due to XCount′ not being greater or XCount′ becomes the count value with the highest order tag.

The refresh state controller 242 may receive the auto-refresh signal REF and determine what type and how many refresh operations should occur. The refresh state control circuit 242 provides one or more activations of internal refresh signals IREF and RHR. Responsive to the activations of the internal refresh signals, the refresh address generator performs a refresh operation (or skips performing a refresh operation if the aggressor detector does not identify an aggressor HitXADD). The refresh state controller 242 provides the signal RHR to indicate a targeted refresh operation. The refresh state controller 242 provides the signal RHR responsive to RFM or based on internal logic responsive to REF. For example, the refresh state controller 242 may provide the RHR signal based on certain number of activations of REF (e.g., every 4th activation of REF) and/or based on a number of activations of IREF. In some embodiments, IREF alone may indicate a sequential refresh operation, while IREF and RHR together indicate a targeted refresh operation. Responsive to REF or RFM, the refresh state control may generate a number of activations of IREF (e.g., a number of pumps) and then activate RHR for the pumps which are used for targeted refresh operation.

Responsive to the signal RHR, the aggressor detector circuit 217 provides the row address from the slot with the highest order tag (e.g., the order tag with the largest value) as an aggressor address HitXADD. If the queue 244 is empty, the aggressor detector circuit 217 will not provide an aggressor address and the targeted refresh operation may be skipped. In some embodiments, before providing an address as HitXADD, the count value associated with that address may be compared to a threshold. If the count value has not crossed the threshold, then no address is provided as the aggressor address HitXADD and the targeted refresh operation is skipped. If the count value has crossed the threshold, then the address (associated with the top of the queue 244) is provided as HitXADD.

Responsive to one of the stored addresses being provided as HitXADD, the register management circuit 245 may perform an operation to reset the count value associated with that address. The register management circuit 245 may direct the row decoder 208 to read out the count value associated with HitXADD from the counter memory cells 226 to the counter circuit 246. The register management circuit 245 may direct the counter circuit 246 to reset the count value (e.g., to an initial value) and write the reset value back to the counter memory cells 226. The register management circuit 245 also removes the stored address, count value, and order tag from the register 244. This makes the next highest value of order tag become the order tag with the highest position.

The refresh address generator 250 includes a sequential refresh address generator 252 and a targeted refresh address generator 254. The sequential refresh address generator 252 generates a sequential refresh address as the refresh address RXADD when a sequential refresh operation is called for (e.g., when IREF is active but RHR is not). The sequential refresh address may be based on a previous sequential refresh address. For example, the sequential refresh address generator may have a counter circuit which increments a previous sequential refresh address value to achieve the next sequential refresh address.

The refresh address generator circuit 250 also includes a targeted refresh address generator circuit 254 which generates a targeted refresh address as the refresh address RXADD when it receives the RHR signal and an identified aggressor address HitXADD. If the signal RHR is provided, but HitXADD is not (e.g., because none of the addresses stored in the candidate register 244 have crossed the threshold) then the targeted refresh address generator may skip the targeted refresh operation by not providing a refresh address RXADD. The targeted refresh address generator 254 may determine the locations of one or more victim rows based on aggressor address HitXADD and provide them as the refresh address RXADD. In some embodiments, the victim rows may include rows which are physically adjacent to the aggressor row (e.g., HitXADD+1 and HitXADD−1). In some embodiments, the victim rows may also include rows which are physically adjacent to the physically adjacent rows of the aggressor row (e.g., HitXADD+2 and HitXADD−2). Other relationships between victim rows and the identified aggressor rows may be used in other examples.

The row decoder 208 may perform one or more operations on the memory array 218 based on the received signals and addresses. For example, responsive to the activation signal ACT and the row address XADD (and IREF and RHR being at a low logic level), the row decoder 208 may direct one or more access operations (for example, a read operation) on the specified row address XADD. Responsive to an address RXADD and one or both of the signals IREF and RHR being active, the row decoder 208 may perform a refresh operation on the word line (or word lines) associated with RXADD. Responsive to the signal RHR being active but no address RXADD (e.g., because no address HitXADD was provided to the refresh address generator 250) then the row decoder 208 may skip the refresh operation.

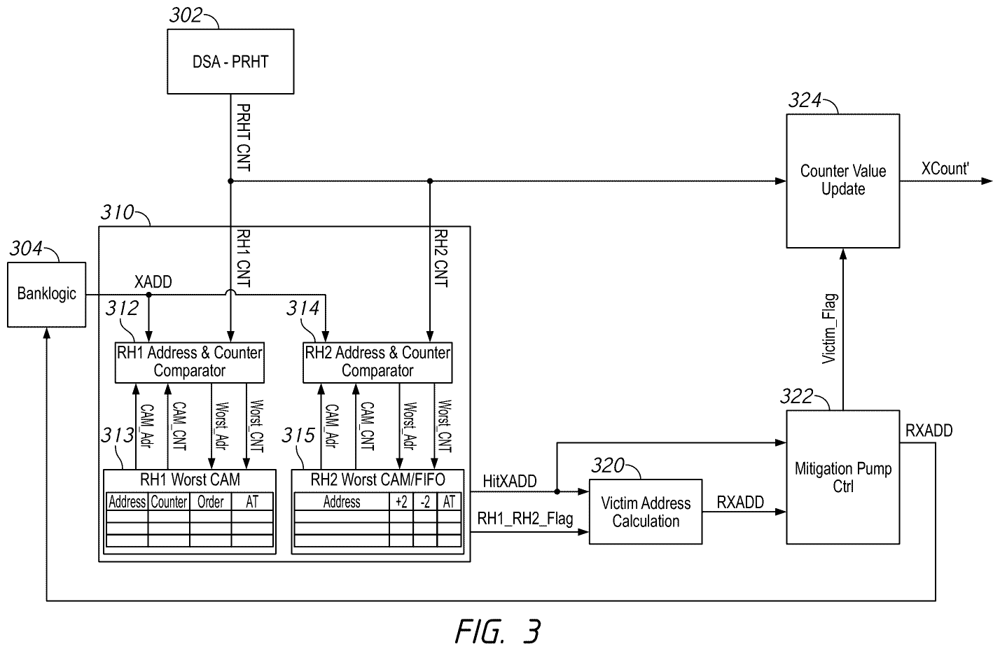

FIG. 3 is a block diagram of an aggressor detector circuit according to some embodiments of the present disclosure. FIG. 3 shows portions of a memory 300 such as the memory 100 of FIGS. 1 and/or 200 of FIG. 2. The aggressor detector circuit 310 may, in some embodiments, implement the aggressor detector circuit 217 of FIG. 2. In the embodiment of FIG. 3, the aggressor detector circuit 310 includes two targeted refresh queues 313 and 315 and their respective register management circuits 312 and 314. The two queues 313 and 315 may be used to store candidate addresses for two different types of targeted refresh operation (e.g., for refreshing +/−1 victims or +/−2 victims). The register management circuits 312 and 314 may use different logic to manage the two queues 313 and 315. Also shown in FIG. 3 are a counter circuit 302 (e.g., 246 of FIG. 2) and bank logic 304, which represents various other components of the refresh control circuit (e.g., the refresh state control 242 of FIG. 2, DRAM interface 240, refresh address generator 250, and/or row decoder 208 of FIG. 2).

The queue 313 is an ordered queue where the stored addresses and count values are kept as an ordered list. The queue 313 may implement the queue 244 of FIG. 2, and the register management circuit 312 may implement the register management circuit 245 of FIG. 2. For the sake of brevity, since the operations of a sorted queue was already described with respect to FIGS. 1 and 2, such details will not be repeated again with respect to the queue 313 and register management circuit 312 of FIG. 3. The queue 315 and refresh management circuit 314 may implement different behavior. For example, rather than being a sorted list, the queue 315 may act as a FIFO or other type of queue. In other words, in the queue 313, the value of the stored count values may determine which slot is at a top of the queue, while in the queue 315 the count value is not used to determine an order.

The two queues 313 and 315 may have a same or different number of slots from each other. The number of slots in the two queues 313 and 315 may, in some embodiments, be based on how many targeted refresh commands are received in a row in a worst case or ‘panic refresh’ scenario. The two queues 313 and 315 may include a number of content addressable memory (CAM) cells which allow comparing an input to the stored value. The register management circuits 312 and 314 can each read out of the stored address CAM_Adr and stored count CAM_CNT from their respective registers 313 and 315, and also write an address Worst_Adr and count Worst_CNT to their respective registers. In some embodiments, the contents of the slots of the two queues 313 and 315 may differ. For example, the first queue 313 may include an order tag in its slots, while the second queue 315 may not.

During an access operation, the bank logic 304 provides a row address XADD along with an activation signal ACT to the memory array such as 118 of FIGS. 1 and/or 218 of FIG. 2 (not shown in FIG. 3). Responsive to the signal ACT, the word line associated with the value of XADD is activated, and the bits stored in the counter memory cells (e.g., 126 of FIGS. 1 and/or 226 of FIG. 2) are read out to the counter circuit 302. The counter circuit 302 updates the count value (e.g., by incrementing it) and provides the updated count value XCount′ to the aggressor detector circuit 310.

Both register management circuits 312 and 314 receive the row address XADD from a row address bus and the updated count value XCount′ from the counter. The count goes to the first register management circuit 312 as RH1 CNT and to the second register management circuit 314 as RH2 CNT. The register management circuits 312 and 314 determine whether or not to add the count value and the row address to their respective queues 313 and 315.

During refresh operations, a first type or a second type of targeted refresh operation may be called for. The first type of targeted refresh operation may refresh word lines which have a first relationship with the identified aggressor, while the second type of targeted refresh operation may refresh word lines which have a second relationship with the identified aggressor. For example, the first type of targeted refresh operation may refresh word lines which are adjacent to the aggressor (e.g., +/−1) while the second type of targeted refresh operation may refresh word lines which are further away (e.g., +/−2). When the bank logic 304 calls for the first type of targeted refresh operation, the first refresh management portion 312 and register 313 may be used. When the bank logic calls for the second type of targeted refresh operation, the second refresh management portion 314 and register 315 may be used.

The bank logic 304 may call for the different types of targeted refresh operation based on internal logic For example, every Nth time the first type of targeted refresh operation is performed, the second type of targeted refresh operation may be performed as the next targeted refresh operation. Based on which type of targeted refresh operation is called for, the row hammer mitigation logic circuit 318 may use different logic to generate the refresh address RXADD.

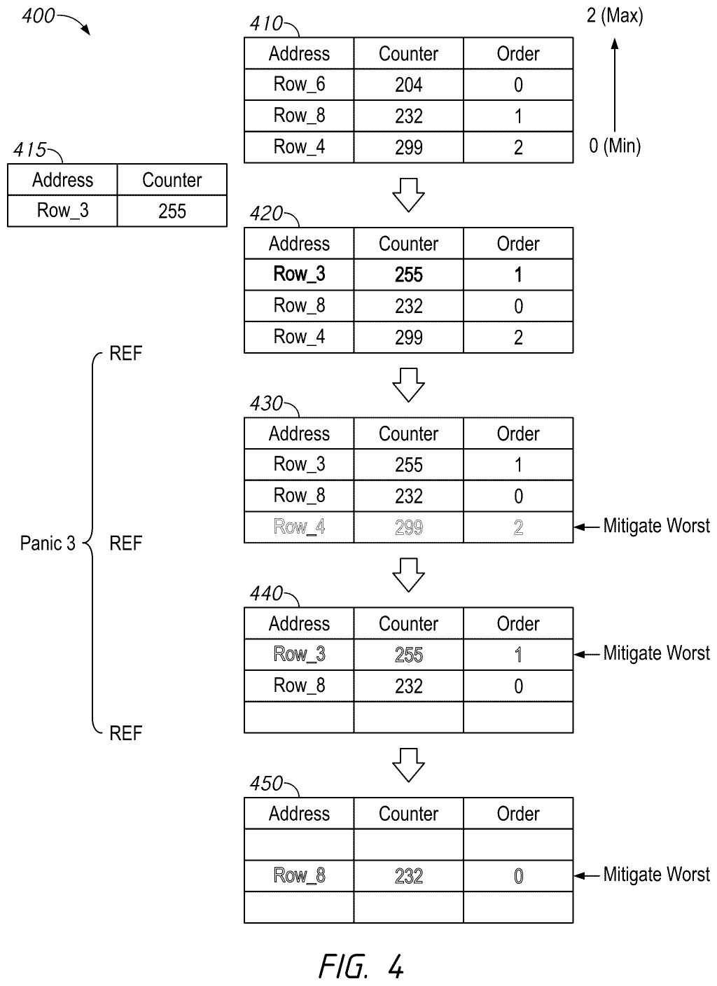

FIG. 4 is a chart of example operations in a targeted refresh queue according to some embodiments of the present disclosure. The chart 400 shows the state of an example queue as different operations are performed. The chart 400 of FIG. 4 may represent the operations of a sorted targeted refresh queue such as 244 of FIGS. 2 and/or 313 of FIG. 3 in some embodiments. In the example embodiment of FIG. 4, a queue with 3 slots is shown. More or fewer slots may be used in other example embodiments.

The chart 400 shows an box 410 of the queue at an initial time. At this time the queue stores 3 addresses, Row_6 with a count of 204 in the first slot, Row_8 with a count value of 232 in the second slot, and Row_4 with a count value of 299 in the third slot. Based on previous sorting, the first slot has the lowest order tag (e.g., 0) the second slot has the middle order tag (e.g., 1), and the third slot has the highest order tag (e.g., 2).

At a time represented by box 415, Row_3 is accessed and its updated count value is 255. Since this is greater than at least one of the stored count values, at the time represented by box 420, new address and count value have been used to overwrite the address and count value in the slot which previously had the lowest order tag. Accordingly, the first slot now contains Row_3 and a count value of 255. Since the contents of the queue were changed, the register management circuit re-sorted the queue, and now first slot has the middle order tag, the second slot has the lowest order tag, and the third slot maintains the highest order tag.

Beginning at a time represented by box 430 a set of targeted refresh operations are performed. The set of refresh operations may be part of a worst case or panic refresh operation. In this example embodiment, 3 targeted refresh operations are performed responsive to the panic refresh. At the time represented by box 430, the address in the queue with the highest order tag is provided as the aggressor address. In this case, that is Row_4, which was stored in the third slot. Responsive to one or more targeted refresh operations based on Row_4, the address, its count and order tag are removed from the queue.

At the next time represented by box 440 a second targeted refresh operation is performed. Since Row_4 and its tag were removed, the slot which has the highest order tag is now the first slot, with an order tag value of 1 (since there is no longer a ‘2’ order tag) . . . Accordingly, one or more targeted refresh operations are performed based on Row_3 from the first slot.

At a next time represented by box 450, a third targeted refresh operation is performed. Since Row_3 and its tag were removed, the final slot, with an order tag of 0, now has the highest order tag. Accordingly one or more targeted refresh operations are performed based on Row_8, and the queue is emptied.

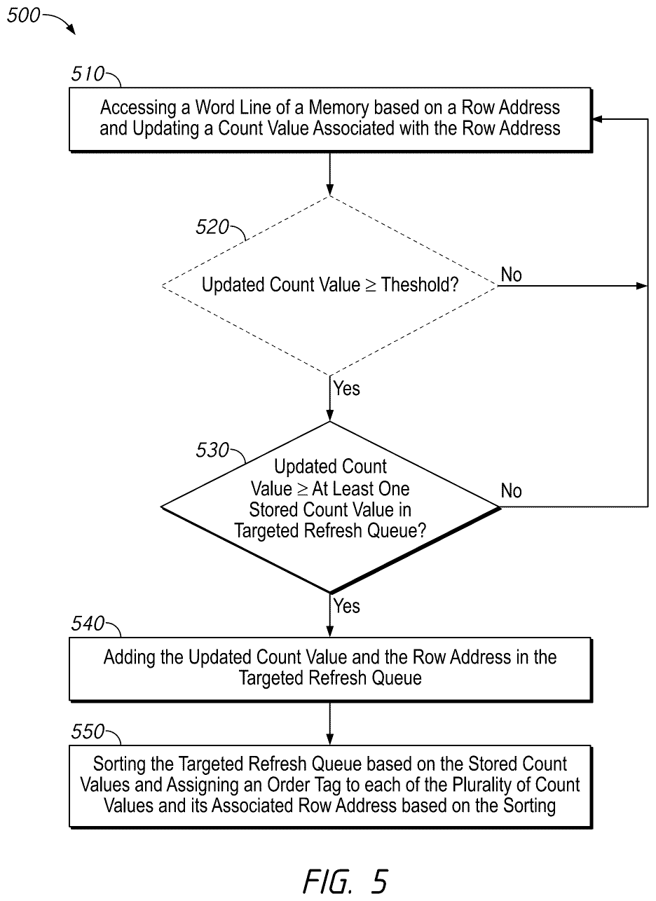

FIG. 5 is a flow chart of a method of managing a targeted refresh queue according to some embodiments of the present disclosure. The method 500 may, in some embodiments, represent operations of a targeted refresh queue such as 244 of FIGS. 2 and/or 313 of FIG. 3 in a memory device such as 100 of FIG. 1, 200 of FIG. 2, and/or 300 of FIG. 3.

The method 500 begins with block 510, which describes accessing a word line of a memory based on a row address and updating a count value associated with the row address. For example the method may include receiving the row address along with an access command (e.g., a read or write command) along C/A terminals of a memory. The method 500 may include providing command signals (e.g., ACT/PRE) from a command decoder (e.g., 106 of FIG. 1) and activating the word line with a row decoder (e.g., 108) based on the row address and the command signals. The method 500 may include reading the count value out from counter memory cells (e.g., 126 of FIGS. 1 and/or 226 of FIG. 2) to a counter circuit (e.g., 246 of FIGS. 2 and/or 324 of FIG. 3). The method 500 may include updating the count value by increasing the count value by a fixed amount (e.g., incrementing the count value). The method 500 may include updating the count value by increasing the count value by a value which changes over time.

In some embodiments, the method 500 includes optional block 520 after block 510, which describes comparing the updated count value to a threshold. If the updated count value has crossed the threshold (e.g., is equal to or greater than the threshold) then the method 500 may proceed to block 530. If the updated count value has not crossed the threshold (e.g., is less than the threshold) then the method 500 my skip boxes 530 to 550 and return to box 510 until a next access operation.

Box 510 is followed by box 530 (or box 520 is followed by box 530 in embodiments where box 520 is used), which describes comparing the updated count value to a plurality of stored count values in a targeted refresh queue (e.g., 244 of FIGS. 2 and/or 313 of FIG. 3) and determining if the updated count value is greater than (or equal to) at least one stored count value in the targeted refresh queue. For example, box 530 may include comparing the updated count value to a stored count value associated with a lowest of the order tags (e.g., the order tag with the smallest value). If the updated count value is greater than (or equal to) at least one stored count value the method proceeds to box 540. If the updated count value is less than (or less than or equal to in some embodiments) all of the stored count values the method 500 may end and return to box 510 until access operation.

In some embodiments, the method 500 may include an extra step (e.g., between boxes 510 and 530 or between boxes 520 and 530) of determining if there is an empty slot in the targeted refresh queue. If there is an empty slot the method 500 may skip box 530 and proceed to box 540 (adding the address and count value to the queue). In some embodiments, if the row address and count value are added to an empty slot, then the updated count value may be changed (e.g., set to the value of the threshold of box 520).

Box 540 describes adding the updated count value and the row address to the targeted refresh queue. In some embodiments, the method 500 may include overwriting the stored count value and stored row address associated with the lowest order tag with the updated count value if the updated count value is equal to or greater than the stored count value. In some embodiments, the stored count value and row address associated with the lowest order tag may be overwritten if the updated count value is greater than the stored count value. In some embodiments, if the address and count value are added to an empty slot, then no existing slot is overwritten.

Box 540 is followed by box 550, which describes sorting the targeted refresh queue based on the stored count values and assigning an order tag to each of the plurality of stored count values and its associated one of the plurality of stared row addresses based on the sorting. For example, the method 500 may include storing a row address, count value, an order tag in one or more of a plurality of slots of the targeted refresh queue, sorting the stored count values and setting a value of the order tags based on the sort. The method 500 may include sorting the targeted refresh queue from a highest stored count value to a lowest stored count value. In some embodiments, the method 500 may include performing a bubble sort to sort the targeted refresh queue (e.g., as described with respect to FIG. 4).

In some embodiments, the method 500 may include storing addresses and count values in a second targeted refresh queue (e.g., 315 of FIG. 3). The second targeted refresh queue may use different logic than the first targeted refresh queue. For example, the method may include sorting the first targeted refresh queue as a list ordered based on the stored count values, but not sorting the second targeted refresh queue based on its stored count values. For example, the second targeted refresh queue may be a FIFO queue.

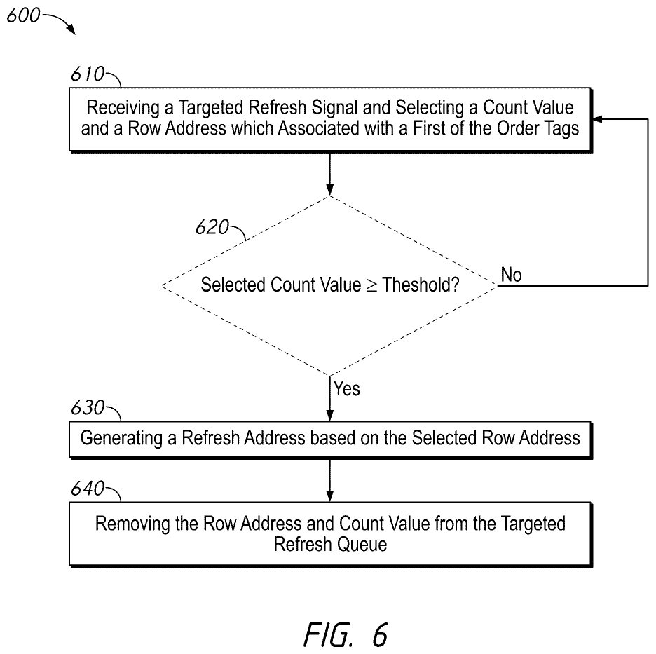

FIG. 6 is a flow chart of a method of performing targeted refresh operations according to some embodiments of the present disclosure. The method 500 may, in some embodiments, represent operations of a targeted refresh queue such as 244 of FIGS. 2 and/or 313 of FIG. 3 in a memory device such as 100 of FIG. 1, 200 of FIG. 2, and/or 300 of FIG. 3. In some embodiments, the method 600 may be a continuation of the method 500. For example, the method 500 may represent how addresses are loaded into and sorted in a targeted refresh queue, while the method 600 may represent how those same addresses in the same queue are used.

The method 600 begins with box 610, which describes receiving a targeted refresh signal and selecting a count value and a row address associated with a first of the order tags in the targeted refresh queue. The method 600 may include receiving a refresh signal (e.g., REF) and then determining whether to perform a normal refresh operation or a targeted refresh operation with a refresh state control circuit 242. The method 600 may include performing the targeted refresh operation responsive to a refresh management (RFM) command. The selecting may include selecting the count value stored in a slot which has a highest value of the order tags

In some embodiments, box 610 is followed by optional box 620, which describes determining if the selected count value has crossed a threshold (e.g., is greater than or equal to the threshold). In some embodiments, either box 520 of FIG. 5 or box 620 may be used. If the selected count value has not crossed the threshold then the targeted refresh operation and boxes 630 and 640 may be skipped. If the selected count value has crossed the threshold, then method 600 proceeds to box 630.

Box 610 may be followed by box 630 (or box 620 may be followed by box 630), which describes generating a refresh address based on the selected row address. For example the refresh address may represent a word line which is adjacent to a word line associated with the selected row address. The method 600 may include refreshing the word line associated with the refresh address as part of the targeted refresh operation.

Box 630 is followed by box 640, which describes removing the selected row address and the selected count value from the targeted refresh queue. For example, the selected row address and selected count value as well as the associated order tag may be removed from the targeted refresh queue. This may make a new order tag the first order tag in the queue.

It is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a targeted refresh queue comprising a plurality of slots, wherein each of the plurality of slots is configured to store a stored address, a stored count value, and an order tag;
a counter circuit configured to update a count value associated with a row address responsive to the row address being accessed;
a register management circuit configured to compare the updated count value to the stored count values in the targeted refresh queue and to store the row address as one of the stored row address and the updated count value as one of the stored count values if the updated count value is greater than at least one of the stored count values and configured to update the order tags based on the stored count values, wherein responsive to a targeted refresh signal the register management circuit is configured to provide the stored row address associated with a first of the order tags as an aggressor address.

2. The apparatus of claim 1, further comprising:
a second targeted refresh queue comprising a second plurality of slots, wherein each of the second plurality of slots is configured to store a stored address; and
a second register management circuit configured to store addresses and provide them in a first-in first-out (FIFO) manner.

3. The apparatus of claim 1, further comprising a refresh address generator configured to generate at least one refresh address based on the aggressor address.

4. The apparatus of claim 1, wherein the register management circuit is further configured to compare the row address to the stored addresses in the plurality of slots, determine if the row address matches one of the stored addresses, and to overwrite the stored count value associated with the matching one of the stored addresses with the updated count value.

5. The apparatus of claim 1, wherein the register management circuit is configured to set a value of the order tags in the plurality of slots based on a comparison of the count values in the plurality of slots to each other.

6. The apparatus of claim 1, wherein the register management circuit is configured to compare the updated count value to a threshold, and skip comparing the updated count value to the stored count values if the updated count value has not crossed the threshold.

7. The apparatus of claim 1, wherein the register management circuit is configured to compare the count value associated with the first of the order tags to a threshold and skip providing the stored row address associated with the first of the order tags as the aggressor address if the count value has not crossed the threshold.

8. An apparatus comprising:
a memory array comprising a plurality of word lines, each associated with one of a plurality of count values;
a row decoder configured to access a selected one of the plurality of word lines responsive to a row address;
a counter circuit configured to update a selected one of the plurality of count values associated with the selected one of the plurality of word lines; and
a targeted refresh queue configured to store a plurality of stored addresses and their associated stored count values as an ordered list, wherein the targeted refresh queue is configured to sort the ordered list responsive to the updated count value, and wherein the targeted refresh queue is configured to provide a selected one of the stored count values at a top of the list as an aggressor address responsive to a targeted refresh signal,
wherein the row decoder is configured to refresh at least one of the plurality of word lines based on the aggressor address responsive to the targeted refresh signal.

9. The apparatus of claim 8, wherein the targeted refresh queue is further configured to compare a selected one of the stored count values at the top of the list to a threshold responsive to the targeted refresh signal and provide the associated stored address as the aggressor address if the selected one of the stored count values has crossed the threshold.

10. The apparatus of claim 8, wherein the targeted refresh queue is configured to compare the updated count value to a threshold and sort the ordered list based on the updated count value responsive to the updated count value having crossed the threshold.

11. The apparatus of claim 8, wherein the targeted refresh queue is configured to store the row address and the updated count value as one of the plurality of stored addresses and their associated count values responsive to the row address not being one of the plurality of stored addresses and the updated count value being greater than one of the stored count values at a bottom of the ordered list.

12. The apparatus of claim 11, wherein the targeted refresh queue is configured to determine if the row address matches one of the plurality of stored addresses and overwrite the associated one of the stored count values with the updated count values if so.

13. The apparatus of claim 8, wherein the targeted refresh queue is configured to sort the ordered list from a highest of the stored count values to a lowest of the stored count values.

14. The apparatus of claim 8, wherein the targeted refresh queue includes a number of slots, each configured to store one of the plurality of stored addresses, the associated one of the stored count values, and an order tag which indicates the slot's position in the ordered list.

15. A method comprising:
accessing a word line of a memory array associated with a row address and updating a count value associated with the word line;
comparing the updated count value to a plurality of stored count values in a targeted refresh queue and adding the updated count value to the plurality of stored count values and the row address to a plurality of stored row addresses in the targeted refresh queue if the updated count value is greater than at least one of the stored count values;
sorting the plurality of count values in the targeted refresh queue and assigning an order tag to each of the plurality of count values and an associated one of the plurality of stored row addresses; and
generating a refresh address based a selected one of the plurality of stored row addresses assigned to a first of the order tags as part of a targeted refresh operation.

16. The method of claim 15, further comprising:
comparing the row address to the plurality of stored row addresses;
determining if one of the stored plurality of row addresses matches the row address; and
overwriting one of the plurality of stored count values associated with the matching one of the stored plurality of row addresses with the updated count value.

17. The method of claim 15, further comprising comparing the updated count value to a threshold before comparing the updated count value to the plurality of stored count values and not comparing the updated count value to the plurality of stored count values if the updated count value has not crossed the threshold.

18. The method of claim 15, further comprising comparing one of the plurality of count values associated with the first of the order tags to a threshold responsive to a targeted refresh signal and not generating the refresh address if the one of the plurality of count values has not crossed the threshold.

19. The method of claim 15, further comprising:
overwriting one of the plurality of stored count values and the associated one of the plurality of stored addresses associated with a last of the order tags with the updated count value and the row address as part of adding the updated count value and the row address to the targeted refresh queue.

20. The method of claim 15, further comprising performing a bubble sort on the plurality of count values and assigning the order tags based on the bubble sort.
